(19) United States
(12) Patent Application Publication
(10) Pub. No.: US 2005/0104195 A1
(43) Pub. Date: May 19, 2005

(54) Heat spreader and semiconductor device package having the same

(75) Inventor: Yaw-Yuh Yang, Tainan (TW)

Correspondence Address: Ladas & Parry, 26 West 61st Street, New York, NY, 10023, US

(73) Assignee: ADVANCED SEMICONDUCTOR ENGINEERING, INC.

(21) Appl. No.: 10/972,689

(22) Filed: Oct. 25, 2004

(30) Foreign Application Priority Data
Nov. 18, 2003 (TW) 092132287

(51) Int. Cl. H01L 23/10; H05K 7/20

(52) U.S. Cl. 257/706; 257/712; 257/717; 257/720; 361/688; 361/710

(57) ABSTRACT

The present invention relates to a heat spreader and a semiconductor device package having the same. The semiconductor device package comprises a substrate, a semiconductor die, a heat spreader, a molding compound and a plurality of solder balls. The die is mounted on the top surface of the substrate. The heat spreader comprises a heat spreader body and a supporting portion, wherein the heat spreader body a concavity that is lowered from an outermost edge to the central portion, and the supporting portion extends outwardly and downwardly from the outermost edge to form a cavity to accommodate the semiconductor die. The molding compound encapsulates the substrate, the semiconductor die and the heat spreader, but a top surface of the heat spreader body is exposed to the air. As a result, the concavity can increase heat dissipation area, provide a cushion effect and avoid the molding compound overflow during encapsulation.

### BACKGROUND OF THE INVENTION

1. Field of the Invention

The present invention relates to a heat spreader and a semiconductor device package having the same, particularly to a heat spreader having a concavity configuration and a semiconductor device package having the same.

2. Description of the Related Art

FIG. 1 shows a cross sectional view of a conventional semiconductor device package 1. The conventional semiconductor device package 1 comprises a substrate 11, a semiconductor die 12, a plurality of bonding wires 13, a heat spreader 14, a molding compound 15 and a plurality of solder balls 16. The substrate 11 has a top surface and a bottom surface. The semiconductor die 12 is mounted on the top surface of the substrate 11. The bonding wires 13 are used for electrically connecting the substrate 11 and the semiconductor die 12.

The heat spreader 14 comprises a heat spreader body 141 and a supporting portion 142. The heat spreader body 141 is a plane and its top surface is an exposing surface which is exposed to the air for dissipating heat after being encapsulated. The supporting portion 142 extends outwardly and downwardly from the outermost edge of the heat spreader body 141 and is in contact with the top surface of the substrate 11 so as to form a cavity to accommodate the semiconductor die 12 and the bonding wires 13.

The molding compound 15 encapsulates the substrate 11, the semiconductor die 12, the bonding wires 13 and the heat spreader 14, but the top surface of the heat spreader body 141 is exposed to the air. The solder balls 16 are formed on the bottom surface of the substrate 11 and are electrically connected to an outer circuit (not shown).

A shortcoming of the conventional semiconductor device package 1 is that during the package process, the entire top surface of the heat spreader body 141 must touch the upper mold; therefore, the top surface of the heat spreader body 141 is required to be totally flat and to match the upper mold closely. Otherwise, when the upper mold moves downwardly and presses the heat spreader body 141, the uneven force distribution on the top surface of the heat spreader body 141 will cause deformation of the heat spreader body 141 and the molding compound 15 overflow. Additionally, the exposing surface of the heat spreader body 141 is just a plane and the heat spreader body 141 is disposed away from the semiconductor die 12, therefore, the heat dissipation area and capacity are limited.

Consequently, there is an existing need for a novel and improved heat spreader and package structure to solve the above-mentioned problem.

### SUMMARY OF THE INVENTION

One objective of the present invention is that the heat spreader is designed to have a concavity configuration so as to decrease the distance between the heat spreader and the semiconductor die, and increase heat dissipation area.

Another objective of the present invention is that the heat spreader is designed to have a stepped configuration so as to avoid the molding compound overflow during encapsulation, and when an upper mold presses the heat spreader, the stepped configuration can provide a cushion effect.

Yet another objective of the present invention is to provide a semiconductor device package comprising a substrate, a semiconductor die, a plurality of bonding wires, a heat spreader and a molding compound. The substrate has a top surface and a bottom surface. The semiconductor die is mounted on the top surface of the substrate. The heat spreader comprises a heat spreader body and a supporting portion, wherein the heat spreader body has a concavity that is lowered from an outermost edge thereof to a central portion thereof, and the supporting portion extends outwardly and downwardly from the outermost edge of the heat spreader body to form a cavity to accommodate the semiconductor die and the bonding wires. The molding compound encapsulates the substrate, the semiconductor die, the bonding wires and the heat spreader, wherein the top side of the heat spreader body is exposed to the air.

### BRIEF DESCRIPTION OF THE DRAWINGS

FIG. 1 shows a cross sectional view of a conventional semiconductor device package;

FIG. 2 shows a cross sectional view of a semiconductor device package according to the first embodiment of the present invention;

FIG. 3 shows a perspective view of the heat spreader according to the first embodiment of the present invention;

FIG. 4 shows a top view of the heat spreader according to the first embodiment of the present invention;

FIG. 5 shows a top view of the heat spreader according to the second embodiment of the present invention;

FIG. 6 shows a perspective view of the heat spreader according to the third embodiment of the present invention;

FIG. 7 shows a cross sectional view of a semiconductor device package according to the fourth embodiment of the present invention; and FIG. 8 shows a perspective view of the heat spreader according to the fourth embodiment of the present invention.

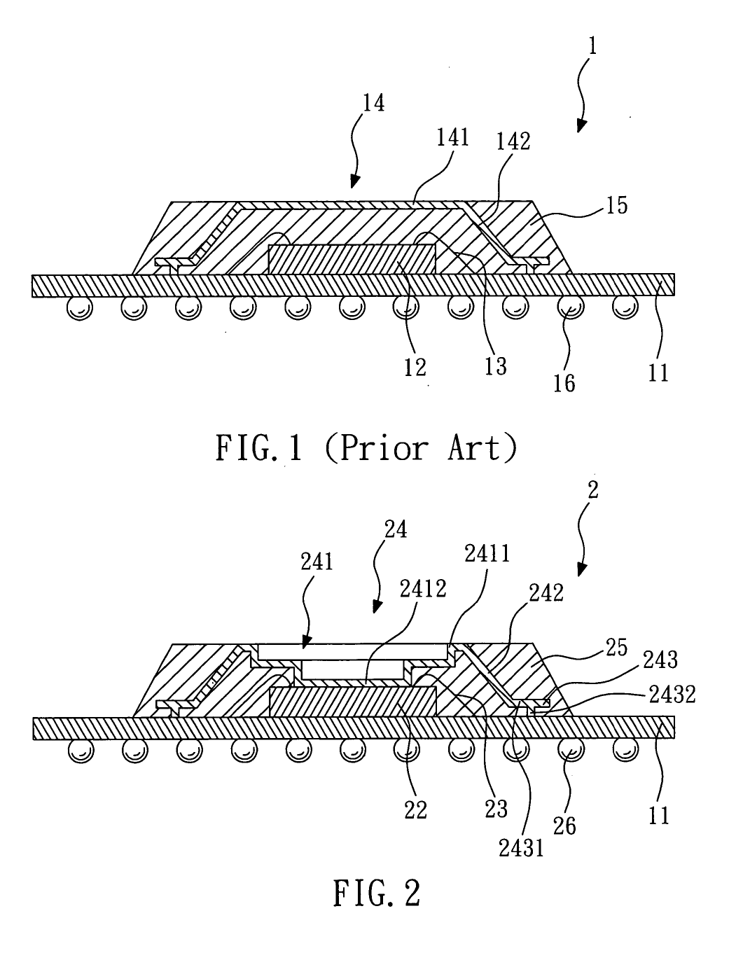

### DETAILED DESCRIPTION OF THE INVENTION

FIG. 2 shows a cross sectional view of a semiconductor device package according to the first embodiment of the present invention. The package 2 comprises a substrate 21, a semiconductor die 22, a plurality of bonding wires 23, a heat spreader 24, a molding compound 25 and a plurality of conductive elements 26.

The substrate 21 has a top surface and a bottom surface. The semiconductor die 22 is mounted on the top surface of the substrate 21. The bonding wires 23 are used for electrically connecting the substrate 21 and the semiconductor die 22. In this embodiment, the semiconductor die 22 is electrically connected to the substrate 21 by utilizing the bonding wires 23. Alternatively, the semiconductor die 22 may be flip-chip bonded to the substrate 21.

The heat spreader 24 accommodates the semiconductor die 22 and the bonding wires 23. The molding compound 25 encapsulates the substrate 21, the semiconductor die 22, the bonding wires 23 and the heat spreader 24, wherein the top side of the heat spreader 24 is exposed to the air. The conductive elements 26 are formed on the bottom surface of the substrate 21 and are electrically connected to an outer circuit (not shown). In this embodiment, the conductive elements 26 are solder balls.

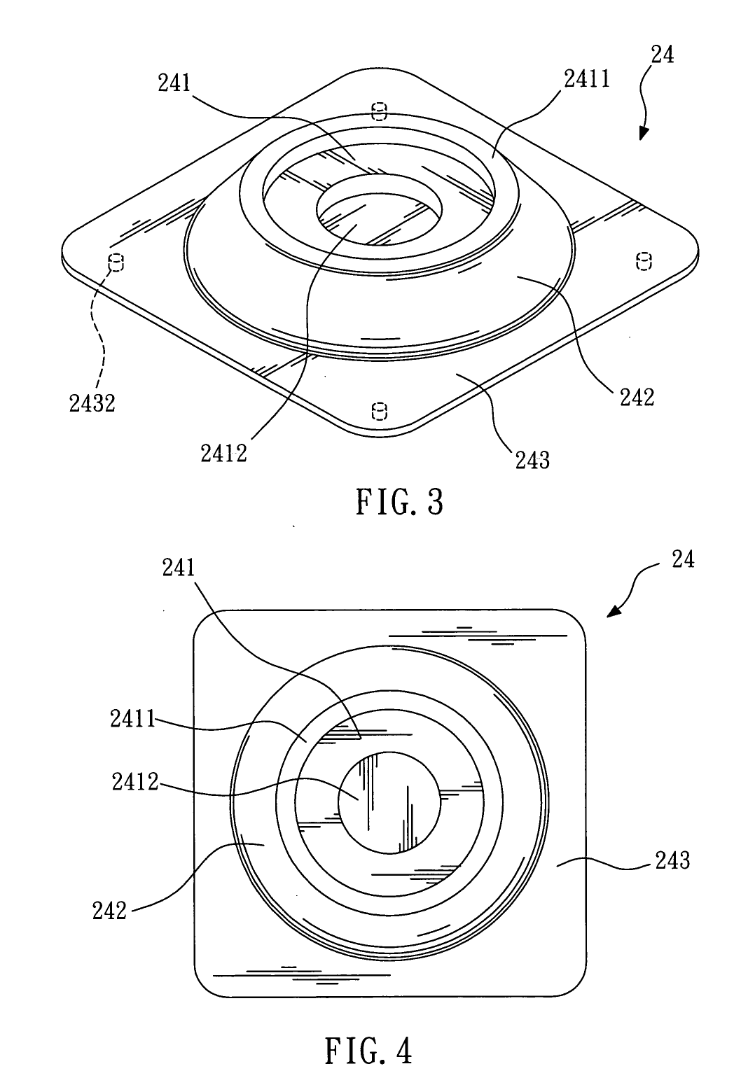

FIG. 3 shows a perspective view of the heat spreader 24 according to the first embodiment of the present invention. The heat spreader 24 comprises a heat spreader body 241, a supporting portion 242 and an annular base 243. The heat spreader body 241 has at least one step to form a concavity that is lowered from an outermost edge 2411 thereof to a central portion 2412 thereof. The outermost edge 2411 is one step, which sustains an upper mold (not shown). Thus, the top surface of the heat spreader body 241 is exposed to the air after being encapsulated. The stepped configuration can not only increase heat dissipation area but also provide a cushion effect when the upper mold presses the heat spreader 24. It is to be noted that the above-mentioned stepped configuration is not limited to the step with an inclination angle of ninety degrees; any kind of step shall be included in the present invention.

The central portion 2412 of the heat spreader body 241 is a plane surface. In this embodiment, the central portion 2412 of the heat spreader body 241 is in contact with the semiconductor die 22. Alternatively, the central portion of the heat spreader body may not be in contact with the semiconductor die.

The supporting portion 242 extends outwardly and downwardly from the outermost edge 2411 of the heat spreader body 241 and is in contact with the top surface of the substrate 21 so as to form a cavity to accommodate the semiconductor die 22 and the bonding wires 23. The annular base 243 is a plate structure that has an opening defined by an inner rim 2431. The bottom of the supporting portion 242 is connected to the inner rim 2431. The annular base 243 has a plurality of protrusions 2432 on the bottom surface thereof, and the protrusions 2432 are in contact with the top surface of the substrate 21.

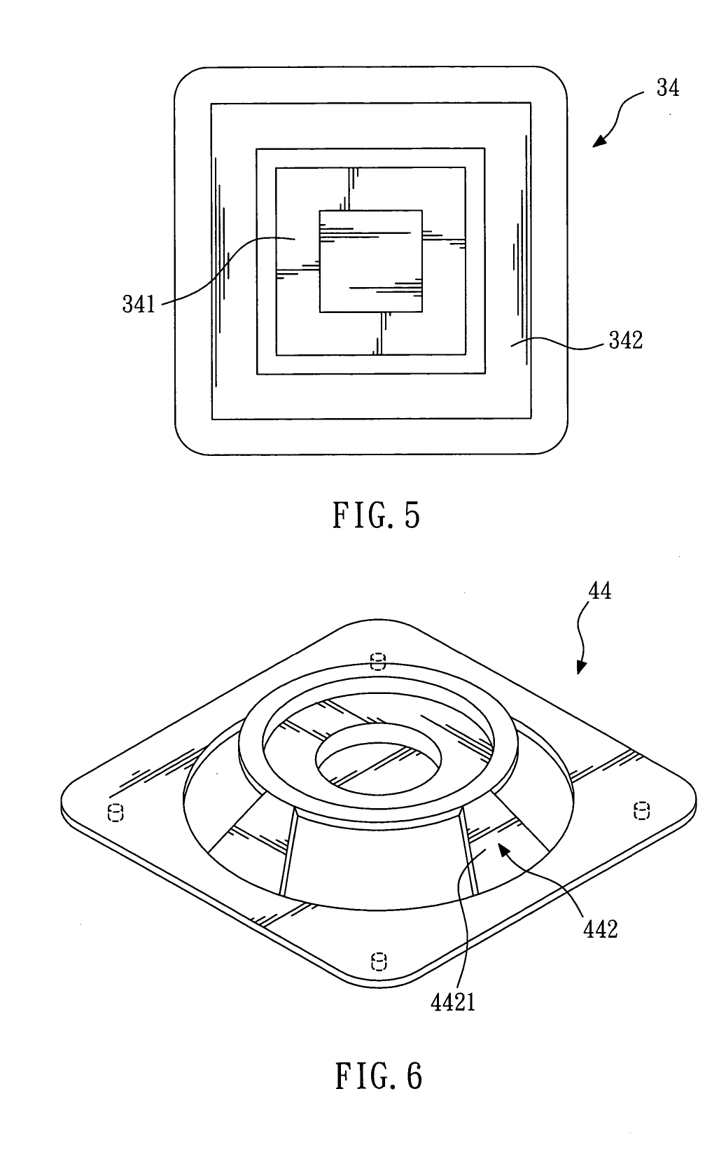

FIG. 4 shows a top view of the heat spreader 24 according to the first embodiment of the present invention. As shown in the figure, from top view, the circumferences of the steps of the heat spreader body 241 are circular and concentric.

FIG. 5 shows a top view of the heat spreader 34 according to the second embodiment of the present invention. This embodiment is substantially equal to the first embodiment, except that the shape of the heat spreader body 341 differs. In this embodiment, from top view, the circumferences of the supporting portion 342 and the steps of the heat spreader body 341 are rectangular and concentric.

FIG. 6 shows a perspective view of the heat spreader 44 according to the third embodiment of the present invention. This embodiment is substantially equal to the first embodiment, except that the shape of the supporting portion 442 differs. In this embodiment, the supporting portion 442 of the heat spreader 44 is constituted by a plurality of discontinuous supporting bars 4421.

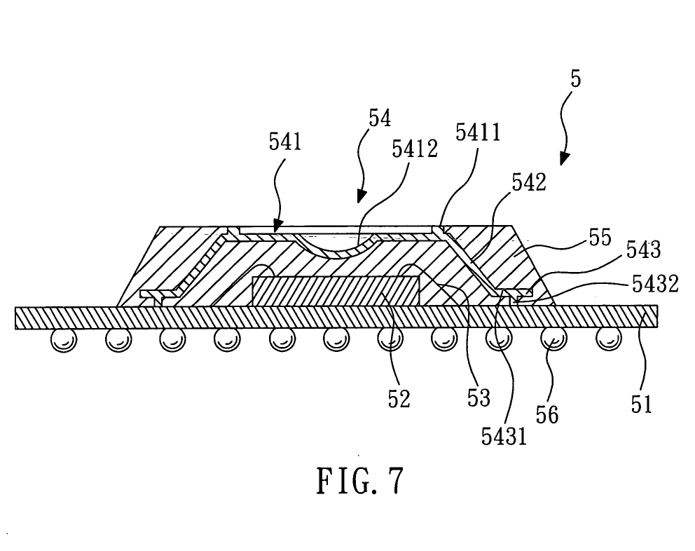

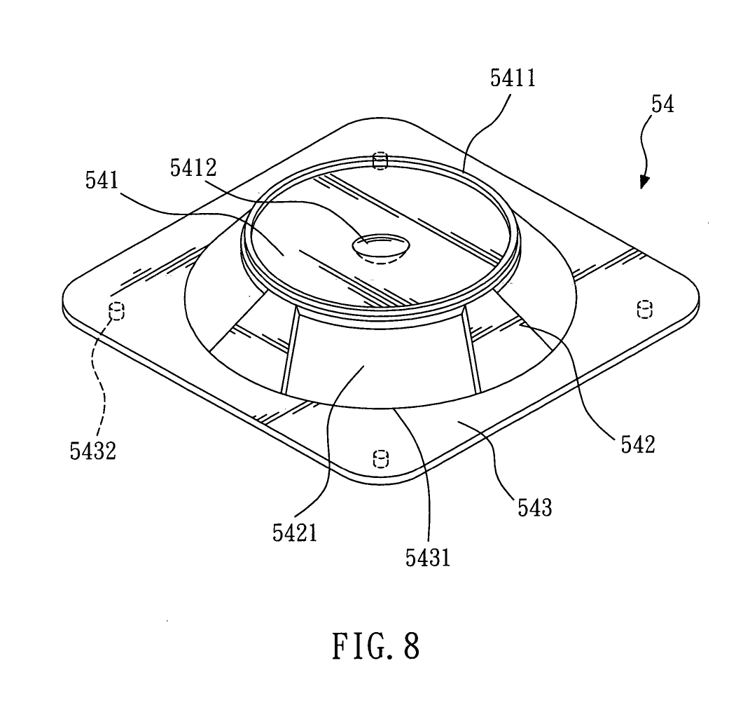

FIG. 7 shows a cross sectional view of a semiconductor device package according to the fourth embodiment of the present invention. The package 5 comprises a substrate 51, a semiconductor die 52, a plurality of bonding wires 53, a heat spreader 54, a molding compound 55 and a plurality of solder balls 56.

The substrate 51 has a top surface and a bottom surface. The semiconductor die 52 is mounted on the top surface of the substrate 51. The bonding wires 53 are used for electrically connecting the substrate 51 and the semiconductor die 52. In this embodiment, the semiconductor die 52 is electrically connected to the substrate 51 by utilizing the bonding wires 53. Alternatively, the semiconductor die 52 may be flip-chip bonded to the substrate 51.

The heat spreader 54 accommodates the semiconductor die 52 and the bonding wires 53. The molding compound 55 encapsulates the substrate 51, the semiconductor die 52, the bonding wires 53 and the heat spreader 54, wherein the top side of the heat spreader 54 is exposed to the air. The solder balls 56 are formed on the bottom surface of the substrate 51 and are electrically connected to an outer circuit (not shown).

FIG. 8 shows a perspective view of the heat spreader 54 according to the fourth embodiment of the present invention. The heat spreader 54 comprises a heat spreader body 541, a supporting portion 542 and an annular base 543. The heat spreader body 541 has a concavity 5412 that is lowered from its outermost edge to its central portion. In this embodiment, the concavity 5412 has a curve surface, and more specifically, it is semicircular. In this embodiment, the central portion of the concavity 5412 of the heat spreader body 541 is not in contact with the semiconductor die 52. Alternatively, the central portion of the concavity may be in contact with the semiconductor die.

The heat spreader body 541 further has a protrusion portion 5411 on the circumference thereof, which is adapted to sustain the upper mold. Thus, the top surface of the heat spreader body 541 and the top surface of the concavity 5412 are exposed to the air after being encapsulated. It is to be understood that the protrusion portion 5411 is not a necessary element of the present invention. The concavity 5412 can not only increase the heat dissipation area but also decrease the distance between the heat spreader 54 and the semiconductor die 52 so as to increase heat dissipation efficiency.

The supporting portion 542 extends outwardly and downwardly from the outermost edge of the heat spreader body 541 and is in contact with the top surface of the substrate 51 so as to form a cavity to accommodate the semiconductor die 52 and the bonding wires 53. The annular base 543 is a plate structure that has an opening defined by an inner rim 5431. The bottom of the supporting portion 542 is connected to the inner rim 5431. The annular base 543 has a plurality of protrusions 5432 on the bottom surface thereof, and the protrusions 5432 are in contact with the top surface of the substrate 51.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

1. A semiconductor device package comprising:
a substrate having a top surface and a bottom surface;
a semiconductor die mounted on the top surface of the substrate;
a heat spreader comprising a heat spreader body and a supporting portion, wherein the heat spreader body has a concavity, and the supporting portion connects with the heat spreader body to form a cavity to accommodate the semiconductor die;
a molding compound used for encapsulating the substrate, the semiconductor die and the heat spreader, wherein the heat spreader body has a exterior side which is to be exposed to the outside of the molding compound; and
a plurality of conductive elements formed on the bottom surface of the substrate.

2. The package according to claim 1, wherein the concavity has a curve surface.

3. The package according to claim 1, wherein the heat spreader body has at least one step to form the concavity.

4. The package according to claim 1, wherein the step of the heat spreader body is circular from top view.

5. The package according to claim 2, wherein the circumferences of the steps of the heat spreader body are concentric from top view.

6. The package according to claim 1, wherein the central portion of the concavity is in contact with the semiconductor die.

7. The package according to claim 1, wherein the supporting portion comprises a plurality of supporting bars.

8. The package according to claim 1, wherein the heat spreader further comprises an annular base, wherein the annular base has an opening defined by an inner rim, and a bottom of the supporting portion is connected to the inner rim.

9. The package according to claim 8, wherein the annular base has a plurality of protrusions on a bottom surface thereof, and the protrusions are in contact with the top surface of the substrate.

10. The package according to claim 1, further comprising a plurality of bonding wires used for electrically connecting the substrate and the semiconductor die.

11. The package according to claim 1, wherein the semiconductor die is flip-chip bonded to the substrate.

12. The package according to claim 1, wherein the conductive elements are solder balls.

13. A heat spreader used for a semiconductor device package having a semiconductor die, the heat spreader comprising:
a heat spreader body having a concavity that is lowered from a outermost edge thereof to a central portion thereof; and
a supporting portion extending outwardly and downwardly from the outermost edge of the heat spreader body to form a cavity to accommodate the semiconductor die.

14. The heat spreader according to claim 13, wherein the concavity has a curve surface.

15. The heat spreader according to claim 13, wherein the heat spreader body has at least one step to form the concavity.

16. The heat spreader according to claim 15, wherein the step of the heat spreader body is circular from top view.

17. The heat spreader according to claim 13, wherein the central portion of the concavity is in contact with the semiconductor die.

18. The heat spreader according to claim 13, wherein the supporting portion comprises a plurality of supporting bars.

19. The heat spreader according to claim 13, further comprising an annular base, wherein the annular base has an opening defined by an inner rim, a bottom of the supporting portion is connected to the inner rim.

20. The heat spreader according to claim 19, wherein the annular base has a plurality of protrusions on the bottom surface thereof.
